(19) United States
(12) Patent Application Publication
(10) Pub. No.: US 2023/0366915 A1
(43) Pub. Date: Nov. 16, 2023

(54) OVERCURRENT DETECTING CIRCUIT, SWITCHED CAPACITOR CONVERTER, AND VEHICLE

(71) Applicant: ROHM Co., LTD., Kyoto (JP)

(72) Inventor: Isao Takobe, Kyoto (JP)

(21) Appl. No.: 18/314,275

(22) Filed: May 9, 2023

(30) Foreign Application Priority Data
May 11, 2022 (JP) 2022-078103

(51) Int. Cl. G01R 19/165; G01R 15/04; H02M 3/06

(52) U.S. Cl. CPC G01R 19/16571; G01R 15/04; H02M 3/06

(57) ABSTRACT

Disclosed is an overcurrent detecting circuit configured to detect an overcurrent of a current output from a switched capacitor converter including a plurality of capacitors and a plurality of switching elements, the overcurrent detecting circuit including a first application terminal configured such that an input voltage of the switched capacitor converter is applied to the first application terminal, a second application terminal configured such that an output voltage of the switched capacitor converter is applied to the second application terminal, and a detecting unit configured to detect the overcurrent according to a difference between the output voltage and an integral multiple or an integral submultiple of the input voltage.

### CROSS REFERENCE TO RELATED APPLICATIONS

This US. application claims priority benefit of Japanese Patent Application No. JP 2022-078103 filed in the Japan Patent Office on May 11, 2022. Each of the above-referenced applications is hereby incorporated herein by reference in its entirety.

### BACKGROUND

The disclosure described in the present specification relates to an overcurrent detecting circuit, a switched capacitor converter, and a vehicle.

In the related art, a switched capacitor converter is used as a power supply (see Japanese Patent Laid-open No. 2006-54955, for example).

The switched capacitor converter has a configuration that includes a plurality of connection nodes between switching elements and in which capacitors are appropriately connected to and between the connection nodes. The switched capacitor converter generates an output voltage by subjecting an input voltage to direct current/direct current (DC/DC) conversion.

### BRIEF DESCRIPTION OF THE DRAWINGS

FIG. 1 is a diagram illustrating a comparative example of a switched capacitor converter;

FIG. 2 is a timing diagram illustrating voltages of various parts of the switched capacitor converter illustrated in FIG. 1;

FIG. 3 is a diagram illustrating a switched capacitor converter according to an embodiment;

FIG. 4 is a diagram illustrating an example of a configuration of an overcurrent detecting circuit;

FIG. 5 is a diagram illustrating an example of a configuration of a constant current source;

FIG. 6 is an external view of a vehicle;

FIG. 7 is a diagram illustrating a first example of a switched capacitor converter having a topology different from a Dickson topology;

FIG. 8 is a diagram illustrating a second example of a switched capacitor converter having a topology different from the Dickson topology;

FIG. 9 is a diagram illustrating a third example of a switched capacitor converter having a topology different from the Dickson topology; and

FIG. 10 is a diagram illustrating a fourth example of a switched capacitor converter having a topology different from the Dickson topology.

### DETAILED DESCRIPTION

In the present specification, a metal oxide semiconductor (MOS) field-effect transistor refers to a field-effect transistor in which a gate structure includes at least the following three layers: a “layer including a conductor or a semiconductor such as polysilicon having a small resistance value,” an “insulating layer,” and a “P-type, N-type, or intrinsic semiconductor layer.” That is, the gate structure of the MOS field-effect transistor is not limited to a three-layer structure of metal, an oxide, and a semiconductor.

In the present specification, a reference voltage refers to a fixed voltage in an ideal state. In practice, the reference voltage is a voltage that can slightly vary according to a temperature change or other factors.

In the present specification, a constant current refers to a fixed current in an ideal state. In practice, the constant current is a current that can slightly vary according to a temperature change or other factors.

### <Switched Capacitor Converter (Comparative Example)>

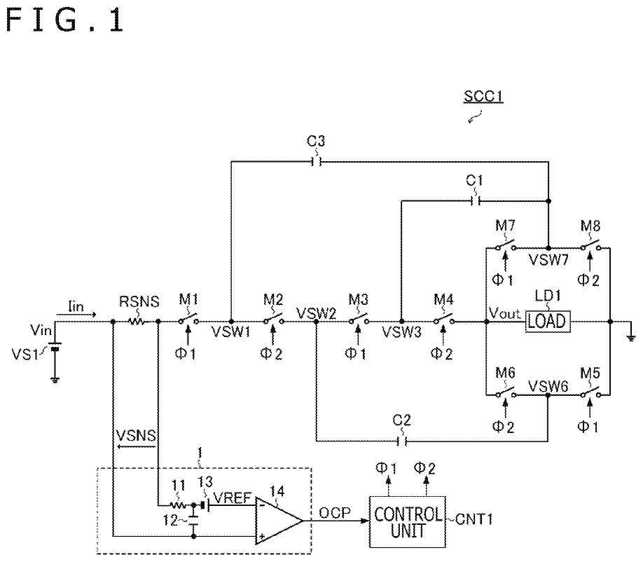

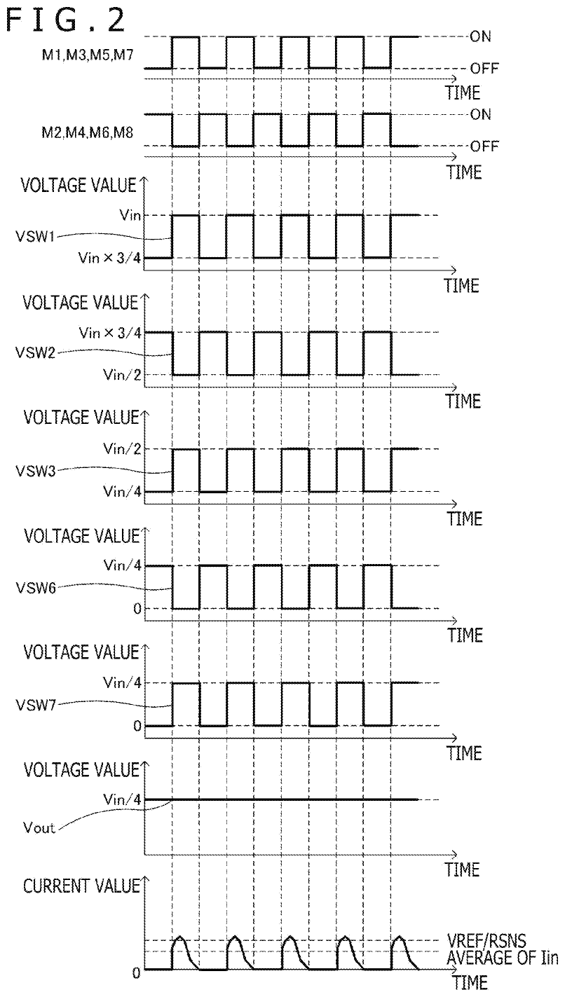

FIG. 1 is a diagram illustrating a comparative example of a switched capacitor converter (typical configuration to be compared with an embodiment to be described later). The topology of a switched capacitor converter SCC1 according to the present comparative example is a Dickson topology. FIG. 2 is a timing diagram illustrating voltages of various parts of the switched capacitor converter SCC1.

The switched capacitor converter SCC1 includes switching elements M1 to M8, capacitors C1 to C3, an output capacitor Cout, a control unit CNT1, a sense resistance RSNS, and an overcurrent detecting circuit 1.

A first terminal of the switching element M1 is connected to a positive electrode of a direct-current voltage source VS1 via the sense resistance RSNS. A negative electrode of the direct-current voltage source VS1 is connected to a ground potential. The direct-current voltage source VS1 supplies an input voltage Vin to the first terminal of the switching element M1.

A second terminal of the switching element M1 is connected to a first terminal of the switching element M2 and a first terminal of the capacitor C3. A second terminal of the switching element M2 is connected to a first terminal of the switching element M3 and a first terminal of the capacitor C2. A second terminal of the switching element M3 is connected to a first terminal of the switching element M4 and a first terminal of the capacitor C1.

A second terminal of the switching element M4 is connected to a first terminal of the switching element M7, a first terminal of a load LD1, a first terminal of the switching element M6, and a first terminal of the output capacitor Cout. A second terminal of the switching element M7 is connected to a first terminal of the switching element M8, a second terminal of the capacitor C1, and a second terminal of the capacitor C3. A second terminal of the switching element M6 is connected to a first terminal of the switching element M5 and a second terminal of the capacitor C2. A second terminal of the switching element M8, a second terminal of the load LD1, a second terminal of the switching element M5, and a second terminal of the output capacitor Cout are connected to the ground potential.

The control unit CNT1 controls the switching elements M1, M3, M5, and M7 by a first control signal ϕ1, and controls the switching elements M2, M4, M6, and M8 by a second control signal ϕ2.

The control unit CNT1 complementarily performs on/off control of the switching elements M1, M3, M5, and M7 and the switching elements M2, M4, M6, and M8.

A switching voltage VSW1 switches between a value of Vin and a value of Vin×¾. The switching voltage VSW1 occurs at a connection node between the switching element M1 and the switching element M2.

A switching voltage VSW2 switches between a value of Vin×¾ and a value of Vin/2. The switching voltage VSW2 occurs at a connection node between the switching element M2 and the switching element M3.

A switching voltage VSW3 switches between a value of Vin/2 and a value of Vin/4. The switching voltage VSW3 occurs at a connection node between the switching element M3 and the switching element M4.

A switching voltage VSW6 switches between a value of Vin/4 and zero (ground potential). The switching voltage VSW6 occurs at a connection node between the switching element M5 and the switching element M6.

A switching voltage VSW7 switches between a value of Vin/4 and zero (ground potential). The switching voltage VSW7 occurs at a connection node between the switching element M7 and the switching element M8.

An output voltage Vout has a value of Vin/4. The output voltage Vout occurs at a connection node between the switching element M4, the switching element M6, and the switching element M7. The output voltage Vout is supplied to the load LD1.

The sense resistance RSNS converts an input current Iin of the switched capacitor converter SCC1 into a voltage VSNS. The voltage VSNS is supplied to the overcurrent detecting circuit 1. The overcurrent detecting circuit 1 includes a resistance 11, a capacitor 12, a direct-current voltage source 13 that outputs a reference voltage VREF, and a comparator 14.

The input current Iin is a pulsed current, as illustrated in FIG. 2. Thus, in a case where the load LD1 is a heavy load, the voltage VSNS may become higher than the reference voltage VREF due to an inrush current at a rising edge of the pulsed current, so that an overcurrent may be erroneously detected.

An RC filter including the resistance 11 and the capacitor 12 smooths the voltage VSNS to prevent an erroneous detection of an overcurrent. The comparator 14 compares the voltage smoothed by the RC filter, with the reference voltage VREF. When the voltage smoothed by the RC filter is equal to or higher than the reference voltage VREF, the comparator 14 detects an overcurrent, and sets an overcurrent protection signal OCP to a HIGH level. When the voltage smoothed by the RC filter is lower than the reference voltage VREF, on the other hand, the comparator 14 does not detect an overcurrent, and sets the overcurrent protection signal OCP to a LOW level.

When the overcurrent protection signal OCP is at the HIGH level, the control unit CNT1 performs an overcurrent protecting operation that stops the switching control of the switching elements M1 to M8 and turns off all of the switching elements M1 to M8.

The switched capacitor converter SCC1 is decreased in efficiency because a loss occurs at the sense resistance RSNS. In addition, an increase in the number of parts is caused in a case where the RC filter including the resistance 11 and the capacitor 12 is a part external to a semiconductor integrated circuit device including the control unit CNT1.

In view of the above-described considerations, in the following, there is proposed a novel embodiment which can detect an overcurrent without inviting a decrease in efficiency of the switched capacitor converter.

### <Switched Capacitor Converter (Embodiment)>

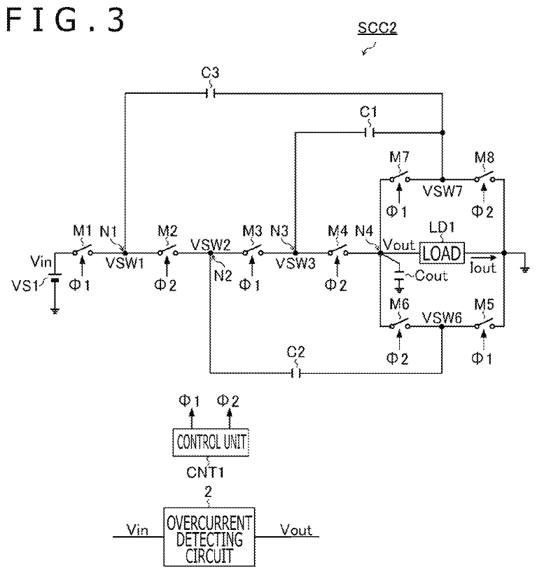

FIG. 3 is a diagram illustrating an embodiment of a switched capacitor converter. A switched capacitor converter SCC2 according to the present embodiment is different from the switched capacitor converter SCC1 described above in that the switched capacitor converter SCC2 has an overcurrent detecting circuit 2 in place of the sense resistance RSNS and the overcurrent detecting circuit 1. Otherwise, the switched capacitor converter SCC2 is basically similar to the switched capacitor converter SCC1 described above.

In a switched capacitor converter under no load, the output voltage is expressed by an integral multiple or an integral submultiple of the input voltage. In the switched capacitor converter SCC2 under no load, the output voltage Vout is ¼ times the input voltage Vin.

The switched capacitor converter does not perform feedback control, but controls the switching elements in an open loop. Thus, in the switched capacitor converter, the output voltage Vout drops according to an output current Iout. When the switched capacitor converter SCC2 is under load, the following Equation (1) holds between the output voltage Vout, the input voltage Vin, and the output current Iout.

Vout=Vin/4−Rout×Iout (1)

When the control unit CNT1 operates the switching elements M1 to M8 at a low switching frequency Fsw, the following Equation (2) holds. An effective capacitance value Cep of the switched capacitor converter SCC2 can be calculated by a method disclosed in Michael D. Seeman and Seth R. Sanders, “Analysis and Optimization of Switched-Capacitor DC-DC Converters” (IEEE TRANSACTIONS ON POWER ELECTRONICS, VOL. 23, NO. 2, MARCH 2008), for example.

Rout≈1/(Cep×Fsw) (2)

Because the relation of the above Equation (1) holds, the overcurrent detecting circuit 2 detects an overcurrent of the output current Iout according to a difference between the output voltage Vout and an integral submultiple of the input voltage Vin. The overcurrent detecting circuit 2 can detect the overcurrent without the sense resistance RSNS being provided. Hence, the overcurrent detecting circuit 2 can detect the overcurrent without inviting a decrease in efficiency of the switched capacitor converter SCC2.

FIG. 4 is a diagram illustrating an example of a configuration of the overcurrent detecting circuit 2. The overcurrent detecting circuit 2 illustrated in FIG. 4 includes resistances R1 to R6, an operational amplifier OP1, P-channel MOS field-effect transistors Q1 to Q3, N-channel MOS field-effect transistors Q4 and Q5, a constant current source IS1, a comparator COMP1, a first application terminal T1, and a second application terminal T2. The input voltage Vin, for example, can be used as a power supply voltage VCC of the overcurrent detecting circuit 2 illustrated in FIG. 4.

A voltage dividing circuit including the resistances R1 and R2 divides the input voltage Vin applied to the first application terminal T1, and thereby generates a voltage having a value of Vin/(4N). The value of N is adjusted by the respective resistance values of the resistances R1 and R2. The voltage having the value of Vin/(4N) which is output from the voltage dividing circuit is supplied to a non-inverting input terminal of the operational amplifier OP1. An output terminal of the operational amplifier OP1 is connected to an inverting input terminal of the operational amplifier OP1. The operational amplifier OP1 thus operates as a buffer amplifier.

The voltage having the value of Vin/(4N) which is output from the operational amplifier OP1 is supplied to a series circuit of the resistances R3 and R4. Specifically, the voltage having the value of Vin/(4N) which is output from the operational amplifier OP1 is supplied to a connection node between the resistance R3 and the resistance R4.

A first current mirror circuit and a second current mirror circuit supply the series circuit of the resistances R3 and R4 with a current corresponding to a constant current Ib output from the constant current source IS1. The first current mirror circuit includes the MOS field-effect transistors Q1 to Q3. The second current mirror circuit includes the MOS field-effect transistors Q4 and Q5.

A voltage having a value of Vin/(4N)−VREF/N is supplied from a connection node between the resistance R4 and the MOS field-effect transistor Q5 to an inverting input terminal of the comparator COMP1. The value of VREF/N can be adjusted by the constant current Ib and the resistance value of the resistance R4.

A voltage dividing circuit including the resistances R5 and R6 divides the output voltage Vout applied to the second application terminal T2, and thereby generates a voltage having a value of Vout/N. The value of N is adjusted by the respective resistance values of the resistances R5 and R6. The voltage having the value of Vout/N which is output from the voltage dividing circuit is supplied to a non-inverting input terminal of the comparator COMP1.

When a difference between the input voltage Vin and the output voltage Vout is increased to the threshold value (VREF), the overcurrent protection signal OCP output from the comparator COMP1 is set to a HIGH level. When the overcurrent protection signal OCP is at the HIGH level, the control unit CNT1 performs an overcurrent protecting operation that stops the switching control of the switching elements M1 to M8 and turns off all of the switching elements M1 to M8.

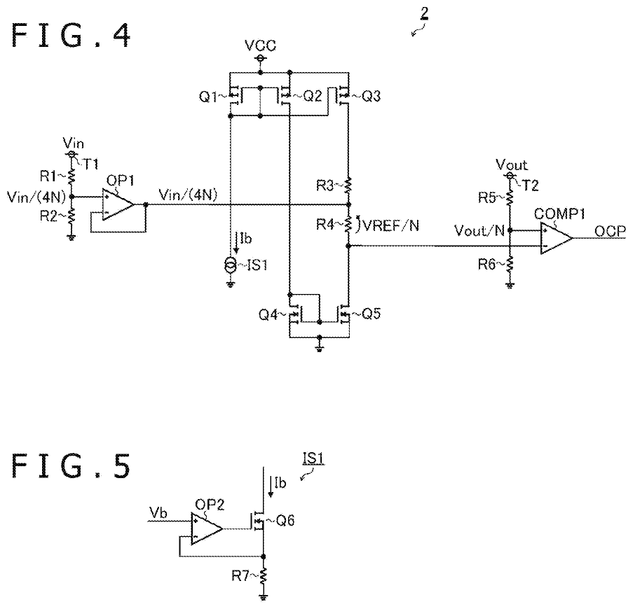

Here, accuracy of the value of VREF can be increased by making the constant current source IS1 have a configuration illustrated in FIG. 5. The constant current source IS1 having the configuration illustrated in FIG. 5 includes an operational amplifier OP2, an N-channel MOS field-effect transistor Q6, and a resistance R7.

A constant voltage Vb is supplied to a non-inverting input terminal of the operational amplifier OP2. The constant voltage Vb is, for example, a highly accurate constant voltage such as a band gap reference voltage. An output terminal of the operational amplifier OP2 is connected to a gate of the MOS field-effect transistor Q6. An inverting input terminal of the operational amplifier OP2 is connected to a source of the MOS field-effect transistor Q6 and a first terminal of the resistance R7. A second terminal of the resistance R7 is connected to a ground potential.

The value of the constant current Ib output from the constant current source IS1 having the configuration illustrated in FIG. 5 can be expressed by the following Equation (3). Incidentally, in the following Equation (3), Ib is the value of the constant current Ib, Vb is the value of the constant voltage Vb, and R7 is the resistance value of the resistance R7.

Ib=Vb/R7 (3)

Letting R be the resistance value of the resistance R4, the above-described VREF can be expressed by the following Equation (4). Hence, the accuracy of the above-described VREF is increased by making characteristics of the resistance R7 and the resistance R3 uniform. The accuracy of detection of overcurrent is consequently increased. Incidentally, the characteristics of the resistance R7 and the resistance R3 can be made uniform by forming the resistance R7 and the resistance R3 in the same manufacturing process, for example.

VREF=Vb×R/R7 (4)

### Examples of Application

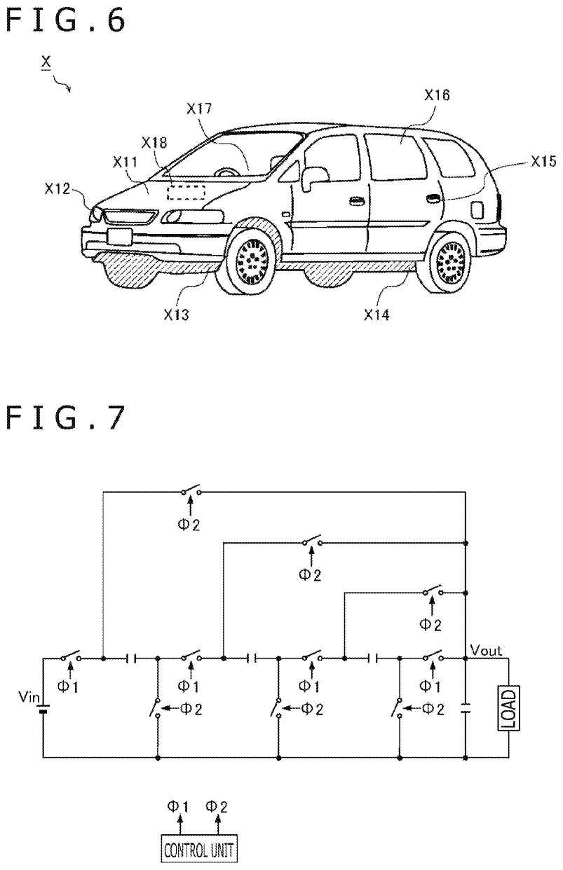

FIG. 6 is an external view of a vehicle X. The vehicle X in the present configuration example is mounted with various electronic apparatuses X11 to X18 that operate by being supplied with a voltage output from an unillustrated battery. It is to be noted that mounting positions of the electronic apparatuses X11 to X18 in the present figure may be different from actual mounting positions for the convenience of illustration.

The electronic apparatus X11 represents an engine control unit that performs control related to an engine (injection control, electronic throttle control, idling control, oxygen sensor heater control, auto-cruise control, and other control).

The electronic apparatus X12 represents a lamp control unit that performs on/off control on a high intensity discharged lamp [HID], a daytime running lamp [DRL], and other lamps.

The electronic apparatus X13 represents a transmission control unit that performs control related to a transmission.

The electronic apparatus X14 represents a braking unit that performs control related to motion of the vehicle X (anti-lock brake system [ABS] control, electric power steering [EPS] control, electronic suspension control, and other control).

The electronic apparatus X15 represents a security control unit that performs driving control on door locks, a crime prevention alarm, and other components.

The electronic apparatus X16 represents electronic apparatuses incorporated in the vehicle X in a stage of factory shipment as standard equipment items or manufacturer option items, such as windshield wipers, electrically operated door mirrors, power windows, dampers (shock absorbers), an electrically operated sunroof, and electrically operated seats.

The electronic apparatus X17 represents electronic apparatuses optionally mounted in the vehicle X as user option items such as a vehicle-mounted audio/visual [A/V] apparatus, a car navigation system, and an electronic toll collection system [ETC].

The electronic apparatus X18 represents electronic apparatuses provided with a high withstand voltage motor, such as a vehicle-mounted blower, an oil pump, a water pump, and a battery cooling fan.

It is to be noted that the switched capacitor converter SCC2 described earlier can be incorporated in any of the electronic apparatuses X11 to X18. In addition, applications of the switched capacitor converter SCC2 described earlier are not limited to a power supply mounted in the vehicle X, and may be a power supply mounted in an industrial apparatus, for example.

### <Others>

In addition to the foregoing embodiment, various changes can be made to the configuration of the disclosure without departing from the spirit of the disclosure. It is to be recognized that the foregoing embodiment is illustrative in all respects, and is not restrictive. It is to be understood that the technical scope of the present disclosure is represented by claims rather than the description of the foregoing embodiment, and includes all changes belonging to meanings and a scope equivalent to the claims.

For example, in the switched capacitor converter SCC2, the dispositions of the direct-current voltage source VS1 and the load LD1 may be interchanged. In a case where the dispositions of the direct-current voltage source VS1 and the load LD1 are interchanged, the voltage supplied from the switched capacitor converter SCC2 to the load LD1 (output voltage of the switched capacitor converter SCC2) is higher than the voltage supplied from the direct-current voltage source VS1 to the switched capacitor converter SCC2 (input voltage of the switched capacitor converter SCC2). In this case, it suffices for the overcurrent detecting circuit to be configured to detect an overcurrent according to a difference between the output voltage of the switched capacitor converter SCC2 and an integral multiple of the input voltage of the switched capacitor converter SCC2.

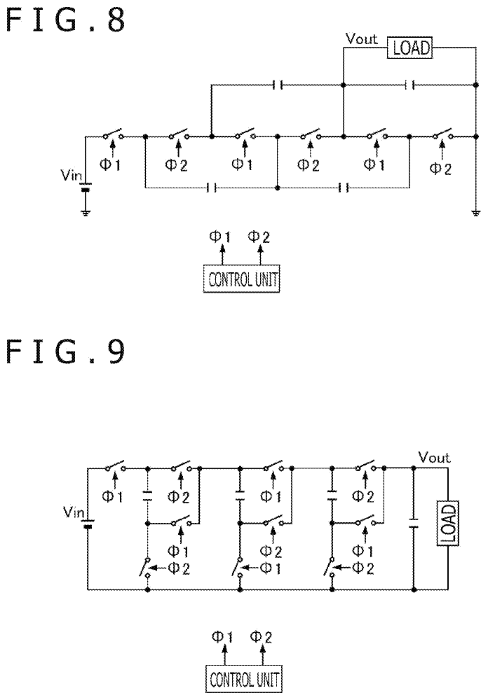

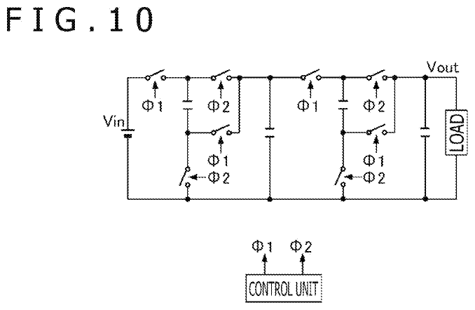

The overcurrent detecting circuit described above can be applied also to switched capacitor converters having topologies different from the Dickson topology. The switched capacitor converters having topologies different from the Dickson topology include, for example, switched capacitor converters illustrated in FIGS. 7 to 10.

The overcurrent detecting circuit (2) described above is an overcurrent detecting circuit configured to detect an overcurrent of a current output from a switched capacitor converter (SCC2) including a plurality of capacitors (C1 to C3) and a plurality of switching elements (M1 to M8), the overcurrent detecting circuit having a configuration (first configuration) including a first application terminal (T1) configured such that an input voltage of the switched capacitor converter is applied to the first application terminal (T1), a second application terminal (T2) configured such that an output voltage of the switched capacitor converter is applied to the second application terminal (T2), and a detecting unit (R1 to R2, R4 to R7, OP1, IS1, Q1 to Q5, and COMP1) configured to detect the overcurrent according to a difference between the output voltage and an integral multiple or an integral submultiple of the input voltage.

The overcurrent detecting circuit having the above-described first configuration can detect the overcurrent without inviting a decrease in efficiency of the switched capacitor converter.

In the overcurrent detecting circuit having the above-described first configuration, there may be adopted a configuration (second configuration) in which the detecting unit includes a first voltage dividing circuit configured to generate a divided voltage of the output voltage and a second voltage dividing circuit configured to generate a divided voltage of the input voltage, and the detecting unit is configured to detect the overcurrent according to a difference between an output of the first voltage dividing circuit and an output of the second voltage dividing circuit.

The overcurrent detecting circuit having the above-described second configuration can reduce voltages to be processed. It is thus possible to achieve a reduction in size and a reduction in cost of the overcurrent detecting circuit.

In the overcurrent detecting circuit having the above-described first or second configuration, there may be adopted a configuration (third configuration) in which the detecting unit detects the overcurrent when the difference between the output voltage and the integral multiple or the integral submultiple of the input voltage is equal to or more than a threshold value, the detecting unit includes a constant current source that includes a first resistance (R7) and that is configured to apply a constant voltage to the first resistance and output a constant current flowing through the first resistance, and a second resistance (R3) configured to be supplied with a current corresponding to the constant current, and the threshold value is determined by a voltage drop across the second resistance.

When characteristics of the first resistance and the second resistance are made uniform, the overcurrent detecting circuit having the above-described third configuration can increase accuracy of detection of the overcurrent.

The switched capacitor converter (SCC2) described above has a configuration (fourth configuration) including the overcurrent detecting circuit having one of the above-described first to third configurations, the plurality of capacitors, and the plurality of switching elements.

The switched capacitor converter having the above-described fourth configuration can detect the overcurrent without inviting a decrease in efficiency.

The vehicle (X) described above has a configuration (fifth configuration) including the switched capacitor converter having the above-described fourth configuration.

The vehicle having the above-described fifth configuration can detect the overcurrent without inviting a decrease in efficiency of the switched capacitor converter.

According to the disclosure described in the present specification, it is possible to detect an overcurrent without inviting a decrease in efficiency of the switched capacitor converter.

What is claimed is:

1. An overcurrent detecting circuit configured to detect an overcurrent of a current output from a switched capacitor converter including a plurality of capacitors and a plurality of switching elements, the overcurrent detecting circuit comprising:
a first application terminal configured such that an input voltage of the switched capacitor converter is applied to the first application terminal;
a second application terminal configured such that an output voltage of the switched capacitor converter is applied to the second application terminal; and
a detecting unit configured to detect the overcurrent according to a difference between the output voltage and an integral multiple or an integral submultiple of the input voltage.

2. The overcurrent detecting circuit according to claim 1, wherein
the detecting unit includes
a first voltage dividing circuit configured to generate a divided voltage of the output voltage, and
a second voltage dividing circuit configured to generate a divided voltage of the input voltage, and
the detecting unit is configured to detect the overcurrent according to a difference between an output of the first voltage dividing circuit and an output of the second voltage dividing circuit.

3. The overcurrent detecting circuit according to claim 1, wherein
the detecting unit detects the overcurrent when the difference between the output voltage and the integral multiple or the integral submultiple of the input voltage is equal to or more than a threshold value,
the detecting unit includes
a constant current source that includes a first resistance and that is configured to apply a constant voltage to the first resistance and output a constant current flowing through the first resistance, and
a second resistance configured to be supplied with a current corresponding to the constant current, and
the threshold value is determined by a voltage drop across the second resistance.

4. A switched capacitor converter comprising:
the overcurrent detecting circuit according to claim 1;
the plurality of capacitor; and
the plurality of switching elements.

5. A vehicle comprising:
the switched capacitor converter according to claim 4.
